(19) United States
(12) Patent Application Publication
(10) Pub. No.: US 2016/0077170 A1
(43) Pub. Date: Mar. 17, 2016

(54) MEDICAL IMAGING APPARATUS WITH A MOVABLY MOUNTED PATIENT BED

(71) Applicant: Siemens Aktiengesellschaft, Muenchen (DE)

(72) Inventors: Ludwig Eberler, Neumarkt i.d. OPf. (DE); Razvan Lazar, Erlangen (DE); Juergen Nistler, Erlangen (DE); Martin Schramm, Erlangen (DE)

(73) Assignee: SIEMENS AKTIENGESELLSCHAFT, Muenchen (DE)

(21) Appl. No.: 14/854,503

(22) Filed: Sep. 15, 2015

(30) Foreign Application Priority Data
Sep. 16, 2014 (DE) 102014218514.9

(51) Int. Cl. G01R 33/30; G01R 33/28

(52) U.S. Cl. CPC G01R 33/307; G01R 33/288

(57) ABSTRACT

A medical imaging apparatus has a patient-receiving area, with a patient bed for supporting a patient and a sliding-support for movable mounting of the patient bed inside the patient-receiving area with the sliding-support has at least one first sliding-support element, which is arranged on the patient bed, and at least two second sliding-support elements, which are arranged inside the patient-receiving area and that engage a first sliding surface of the at least one first sliding-support element. The sliding-support further has at least one third sliding-support element that, when the patient bed is only partially inside the patient-receiving area, engages a second sliding surface of the at least one first sliding-support element.

### BACKGROUND OF THE INVENTION

1. Field of the Invention

The present invention concerns a medical imaging apparatus with a patient-receiving area, a patient bed for supporting a patient and a sliding-support to mount the patient bed inside, and allow movement of the patient bed within, the patient-receiving area, wherein the sliding-support has at least one first sliding-support element arranged on the patient bed, and at least two second sliding-support elements arranged inside the patient-receiving area so that a sliding surface of the at least one first sliding-support element lies on the second sliding-support elements.

2. Description of the Prior Art

A patient bed of a medical imaging apparatus, for example a magnetic resonance (MR) apparatus, is mounted movably inside a patient-receiving area in the direction of its longitudinal extent. The patient bed is designed both for recumbent support of the patient for the medical imaging examination and for positioning the patient by the movable mounting of the patient bed. This results in different requirements for the mounting of the patient bed inside the patient-receiving area. The patient bed must be easy to move so as to facilitate easy positioning. However, the patient bed should also be positioned in a vibration-proof and stable manner during a medical imaging examination. In addition, the patient bed should retain its position during a magnetic resonance examination, during which strong vibrations are produced by the operation of gradient coils.

Particularly in magnetic resonance examinations, during the actual MR data acquisition, the patient should be subjected to as few movements as possible, or move as little as possible, so that a high image quality of the acquired image data can be achieved. This places additional requirements on the patient bed and the mounting of the patient bed particularly in a magnetic resonance apparatus, because the patient bed still has to retain its exact position despite shaking due to patient movement and/or vibrations caused by the operation of the gradient coils.

Conventional medical imaging apparatuses, particularly magnetic resonance apparatuses, have multiple casters arranged inside the patient-receiving area for mounting the patient bed. Conventional medical imaging apparatuses also have a rail arranged on the patient bed that engages the casters, so as to be mounted on the casters, as soon as the patient bed is located inside the patient-receiving area. The casters enable the patient bed to be supported in the direction of a gravitational force acting on the patient bed. Due to friction between the patient bed and the casters, this achieves a stable, secure and safe position for the patient bed inside the patient-receiving area as long as the patient bed is arranged more than 50% inside the patient-receiving area and lies on the corresponding casters.

During the introductory process, the patient bed is only partially arranged inside the patient-receiving area and a center of gravity of the patient bed is outside the patient-receiving area, which can result in movements of the patient bed, such as, for example, tilting of the patient bed in the direction of the gravitational force or against the direction of the gravitational force and/or even movements of the patient bed perpendicular thereto. These movements can be caused by patient movements or result from the vibrations caused by the operation of the gradient coils.

### SUMMARY OF THE INVENTION

An object of the present invention is to facilitate secure and stable positioning of the patient bed during such an introductory process and/or when the patient bed is only partially inside the patient-receiving area.

The invention object is achieved in accordance with the invention by a medical imaging apparatus with a patient-receiving area, a patient bed for supporting a patient and a sliding-support designed for movable mounting of the patient bed inside the patient-receiving area, wherein the sliding-support has at least one first sliding-support element arranged on the patient bed, and at least two second sliding-support elements arranged inside the patient-receiving area so that a first sliding surface of the at least one first sliding-support element lies on the second sliding-support elements.

In accordance with the invention, the sliding-support has at least one third sliding-support element, which in the case of the patient bed being only partially inside the patient-receiving area, engages a second sliding surface of the at least one first sliding-support element. In this context, “the patient bed being only partially inside the patient-receiving area” means that the patient bed is arranged inside the patient-receiving area so that a leading edge of the patient support is inserted no farther than a center of the patient-receiving area, and the rest of the patient bed is located outside the patient-receiving area. In addition, the term “lies on” means that the first sliding surface lies on the second sliding-support elements only when the patient bed is appropriately positioned inside the patient-receiving area. The third sliding-support element engages the second sliding surface when the patient bed is positioned at least as far as the location of the third sliding-support element inside the patient-receiving area.

This achieves an advantageous securing of the position of the patient bed due to support being provided between the different sliding surfaces of the at least one first sliding-support element by the second and third sliding-support elements. Here, in particular, mechanical instability of a position of the patient bed, for example in the case of an only partial arrangement of the patient bed inside the patient-receiving area, and hence unwanted movements of the patient bed, can be advantageously avoided and hence in age artifacts, which can occur during the medical imaging examination as a result of unwanted movements, can be advantageously suppressed.

The two sliding surfaces of the at least one first sliding-support element are preferably arranged on the patient bed such that, despite the advantageous support and position-securing achieved by the two sliding surfaces, an advantageous mobility of the patient bed is retained, for example in order to reposition the patient or to arrange the patient completely inside the patient-receiving area. In this case, advantageously, the first sliding surface of the at least one first sliding-support element is opposite the second sliding surface of the at least one first sliding-support element on the at least one first sliding-support element.

Particularly advantageously, the at least one third sliding-support element is arranged in the direction of a longitudinal extent of the patient-receiving area in the region of the center of the patient-receiving area. For example, in the case of head examinations of the patient, wherein the head of the patient is arranged in a center of the patient-receiving area and the rest of the patient's body is arranged at least partially outside the patient-receiving area, stability of the patient bed is still achieved, by the presence of the at least one third sliding-support element. In addition, in examinations of this kind, due to the at least one third sliding-support element, unwanted instability due to the only partial arrangement of the patient bed inside the patient-receiving area is prevented. In this way, it is possible to prevent movement of the patient bed in the direction of the gravitational force or against the direction of the gravitational force and/or a movement perpendicular to the gravitational force during the examination.

Particularly advantageously, the at least one first sliding-support element is a C-shaped rail. The first C-shaped rail is arranged on an edge (side) region of the patient bed that is parallel to the direction of patient bed movement. This embodiment achieves advantageous mobility of the patient bed inside the patient-receiving area.

In a further embodiment of the invention, the sliding-support comprises two first sliding-support elements, which are arranged on respective edge regions of the patient bed that extend in the direction of a longitudinal extent of the patient bed on the patient bed. This enables a particularly secure mounting of the patient bed inside the patient-receiving area to be achieved by the two first sliding-support elements.

Preferably, in this case, a first of the two first sliding-support elements is arranged on a first edge region of the patient bed and a second of the two first sliding-support elements on a second edge region of the patient bed. The two edge regions are preferably arranged on opposite sides of the patient bed so that a particularly advantageous stability of the patient bed inside the patient-receiving area can be achieved. In addition, a first of the two first sliding-support elements can be a first C-shaped rail and a second of the two first sliding-support elements can be a second C-shaped rail. In this case, the first sliding surface and the second sliding surface preferably form opposite sliding surfaces of the C-shaped rails so that a particularly compact sliding-support unit can be achieved.

In a further embodiment of the invention, the sliding-support has a first roller unit and a second roller unit, with the first roller unit including at least two of the second sliding-support elements and the second roller unit including at least two of the second sliding-support elements. In this case, the second sliding-support elements are formed by roller elements. The roller elements, in particular rotation axes of the roller elements, of the first roller unit are preferably arranged at a distance from one another on a first straight line and the roller elements, in particular rotation axes of the roller elements, of the second roller unit are preferably arranged at a distance from one another on a second straight line with the first roller unit and the second roller unit extending through the patient-receiving area along its entire length. In addition, the first roller unit and the second roller unit are arranged on opposite edge regions of the patient-receiving area. This achieves an advantageous position-securing of the patient bed in any position with respect to the patient-receiving area. Preferably, the roller elements of the first roller unit are guided within the first C-shaped rail of the patient bed and the roller elements of the second roller unit within the second C-shaped rail of the patient bed.

The sliding-support includes two third sliding-support elements, with the first roller unit and the second roller unit each including one of these two third sliding-support elements. This embodiment of the invention enables a particularly stable and secure positioning of the patient bed inside the patient-receiving area even when the patient bed is only partially arranged inside the patient-receiving area such as, for example, for a head examination on the patient. The position of the patient bed can be secured by each C-shaped rail of the patient bed engaging the third sliding-support element of a respective roller unit such that freedom of movement of the patient bed, particularly with an only partial arrangement of the patient bed inside the patient-receiving area, is minimized.

In an embodiment of the invention, the at least one third sliding-support element of the first roller unit is offset from the first straight line of the at least two second sliding-support elements of the first roller unit, and the at least one third sliding-support element of the second roller unit is offset from the second straight line of the at least two second sliding-support elements of the second roller unit. This results in an advantageous support of the roller unit on different sliding surfaces of one of the C-shaped rails and hence freedom of movement of the patient bed is minimized. Preferably, the second sliding-support elements are arranged within the first and second roller units such that a first sliding surface of the C-shaped rail rests on the second sliding-support elements of the first and the second roller units in the direction of the gravitational force. A second sliding surface of the first sliding-support elements opposite the first sliding surface lies against the direction of the gravitational force from below on the third sliding-support element of the first and second roller units.

When the patient bed is introduced into the patient-receiving area, the patient bed is initially only supported by the C-shaped rails and the second sliding-support elements. As soon as the patient bed reaches a central region of the patient-receiving area, an additional mounting of the patient bed is provided via the additional third sliding-support elements. In this case, on a further introduction of the patient bed, the functions of the third sliding-support elements are also utilized without this interfering with the further movement of the patient bed inside the patient-receiving area. If the patient bed is completely introduced inside the patient-receiving area, the weight of the patient can cause a slight sagging of the patient bed and hence the support and/or contact between the third sliding-support element and the sliding surface of the C-shaped rail can be dispensed with.

### BRIEF DESCRIPTION OF THE DRAWINGS

FIG. 1 schematically illustrates a medical imaging apparatus according to the invention.

FIG. 2 schematically illustrates a patient-receiving area, a patient bed and a sliding-support of the medical imaging apparatus according to the invention.

FIG. 3 is a front view of the patient-receiving area, the patient bed and the sliding-support in accordance with the invention.

FIG. 4 is an enlarged view of a portion of the sliding-support in accordance with the invention.

### DESCRIPTION OF THE PREFERRED EMBODIMENTS

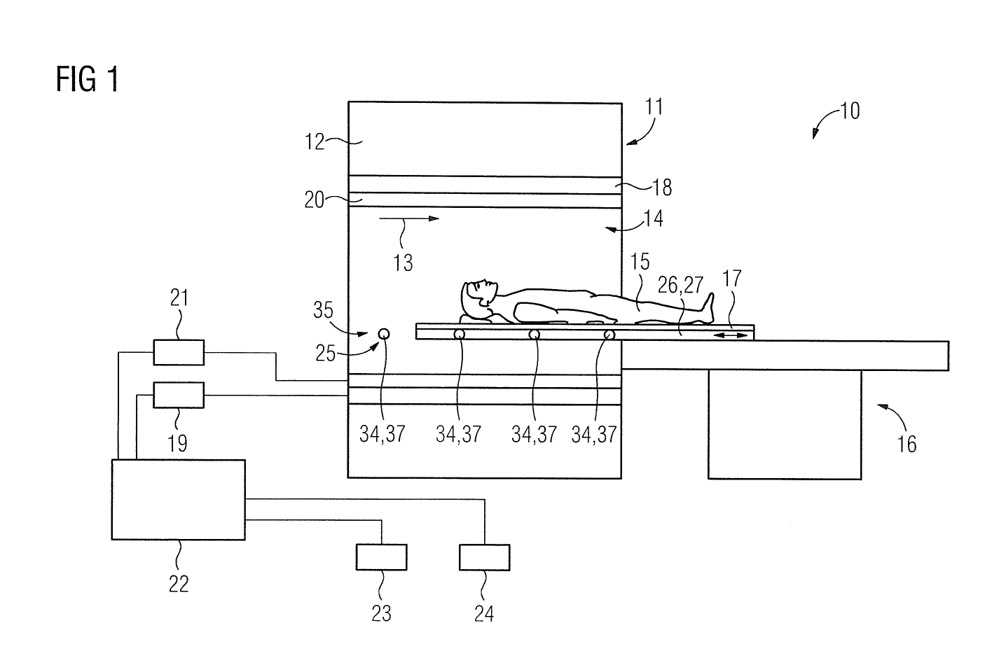

FIG. 1 schematically shows a medical imaging apparatus. In the shown exemplary embodiment, the medical imaging apparatus is formed by a magnetic resonance apparatus 10. However, the embodiment of the medical imaging apparatus is not restricted to a magnetic resonance apparatus 10. The medical imaging apparatus can be formed by any medical imaging apparatus that appears appropriate to those skilled in the art, such as, for example, a computed tomography apparatus, a positron emission tomography apparatus, etc.

The magnetic resonance apparatus 10 has a magnet unit (scanner) 11 having a superconducting basic field magnet 12 to generate a strong and constant basic magnetic field 13. The magnetic resonance apparatus 10 also has a patient-receiving area 14 for receiving a patient 15. In the exemplary embodiment, the patient-receiving area 14 has a cylindrical shape and is surrounded in a circumferential direction by the magnet unit 11. However, in principle a different design of the patient-receiving area 14 is conceivable. The patient 15 can be moved into the patient-receiving area 14 by a patient-support apparatus 16 of the magnetic resonance apparatus 10. To this end, the patient-support apparatus 16 has a movable patient bed 17 inside the patient-receiving area 14.

The magnet unit 11 further has a gradient coil unit 18 that generates magnetic field gradients, which are used for spatial encoding during imaging. The gradient coil unit 18 is controlled by a gradient control unit 19 of the magnetic resonance apparatus 10. The magnet unit 11 further has a radio-frequency (RF) antenna unit 20 to excite nuclear spins so as to depart from the polarization that is established in the basic magnetic field 13 generated by the basic field magnet 12. The radio-frequency antenna unit 20 is controlled by a radio-frequency antenna control unit 21 of the magnetic resonance apparatus 10 and emits radio-frequency magnetic resonance sequences in an examination chamber, which is within the patient-receiving area 14 of the magnetic resonance apparatus 10.

To control the basic magnet 12, the gradient control unit 19 and to control the radio-frequency antenna control unit 21, the magnetic resonance apparatus 10 has a system computer 22. The system control computer 22 controls the magnetic resonance apparatus 19 centrally, such as, for example, for the performance of a predetermined imaging gradient echo sequence. The system control computer 22 also has an evaluation unit (not shown in detail) for the evaluation of medical image data acquired during the magnetic resonance examination. Control information such as, for example, imaging parameters, and reconstructed magnetic resonance images can be displayed for a medical operator on a display unit 23, for example on at least one monitor, of the magnetic resonance apparatus. The magnetic resonance apparatus 10 also has an input unit 24, via which the information and/or parameters can be entered by the medical operator during a measuring procedure.

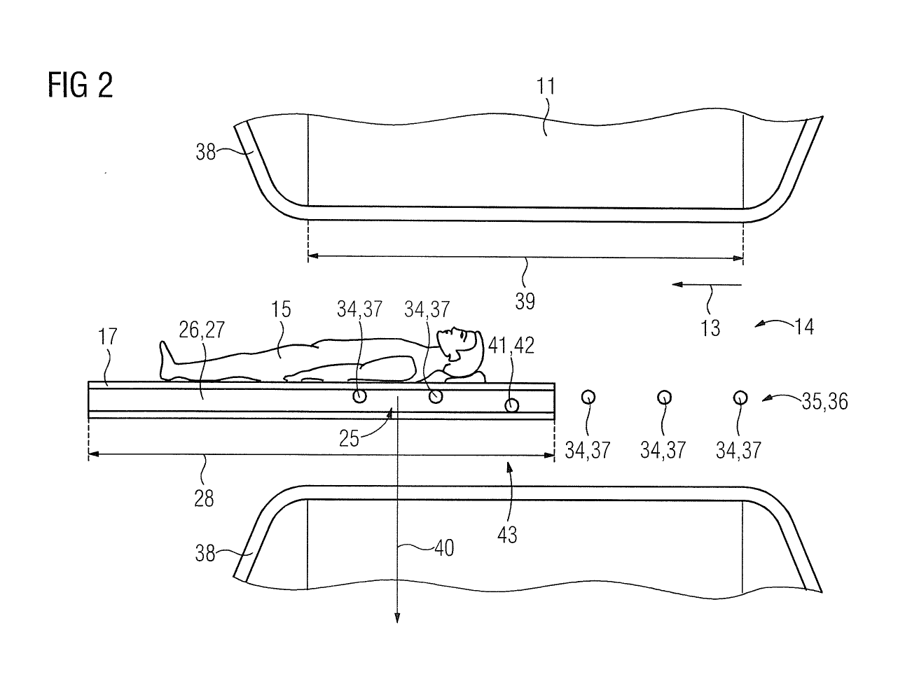

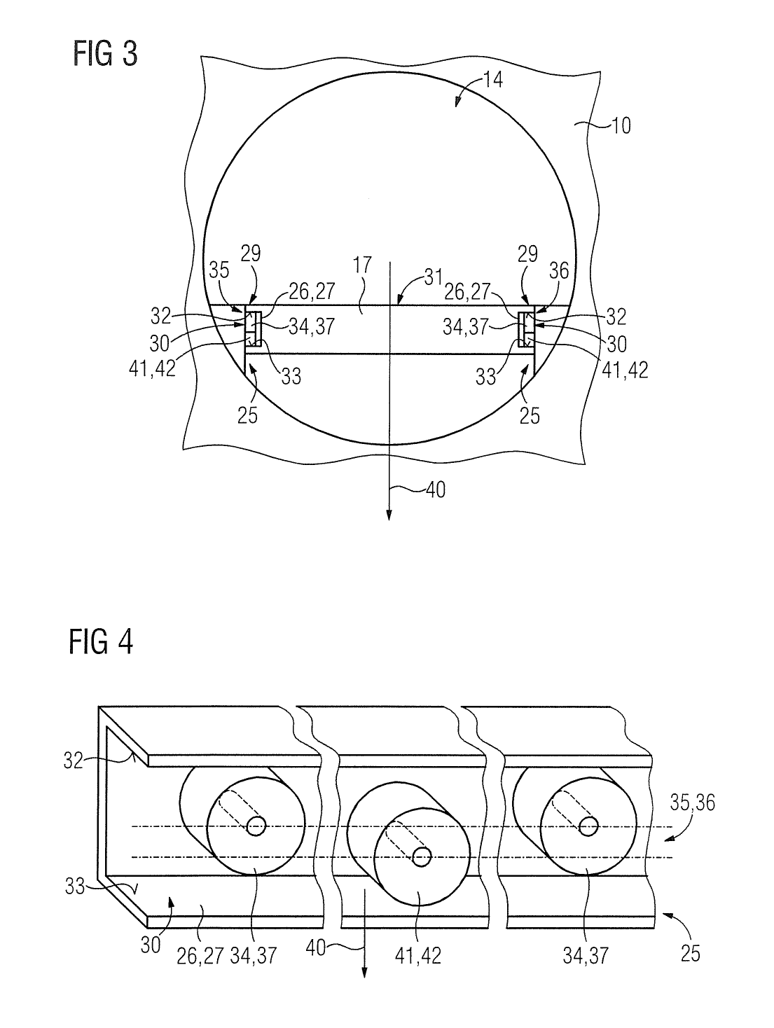

For the movable mounting of the patient bed 17 inside the patient-receiving area 14, the magnetic resonance apparatus 10 has a sliding-support 25. The patient bed 17 together with the sliding-support 25 is shown schematically in more detail in FIGS. 2 to 3.

For movable mounting of the patient bed 17 inside the patient-receiving area 14, the sliding-support 25 has at least one first sliding-support element 26, which is arranged on the patient bed 17. In the present exemplary embodiment, the sliding-support 52 has two first sliding-support elements 26 each including a C-shaped rail 27 (FIGS. 2 and 3). The C-shaped rails 27 extend in the direction of a longitudinal extent 28 on the patient bed 17. To this end, a first of the C-shaped rails 27 is arranged on a first lateral edge region 29 and a second of the C-shaped rails 27 on a second lateral edge region 29 of the patient bed 17, with the first lateral edge region 29 being opposite to the second lateral edge region 29. The two edge regions 29 also extend in the direction of the longitudinal extension 28 of the patient bed 17 on the patient bed 17.

The C-shaped rails 27 each have an opening area 30. The opening area 30 of the two C-shaped rails 27 is in this case directed outwardly so that the opening area 30 of the first C-shaped rail 27 and the opening area 30 of the second C-shaped rail 27 face away from a supporting area 31 of the patient bed 17 on which the patient 15 is supported.

Each of the two C-shaped rails 27 has two sliding surfaces 32, 33 (FIGS. 3 and 4). The two sliding surfaces 32, 33 of a C-shaped rail 27 in each case each face the opening area 30 of the C-shaped rail 27 and are arranged on opposite sides of the C-shaped rail 27. The two sliding surfaces 32, 33 of the respective C-shaped rail 27 extend along an entire longitudinal extension 28 of the patient bed 17 and hence also along an entire longitudinal extension of the C-shaped rails 27 on the C-shaped rails 27.

For movable mounting of the patient bed 17 inside the patient-receiving area 14, the sliding-support unit 25 also has at least two second sliding-support elements 34. In the present exemplary embodiment, the sliding-support 25 includes a first roller unit 35 and a second roller unit 36, which are arranged inside the patient-receiving area 14 (FIGS. 2 and 3). The first roller unit 35 has at least two second sliding-support elements 34 and the second roller unit 36 also has at least two second sliding-support elements 34. Preferably, the first and the second roller units 35, 36 each have at least three or more second sliding-support elements 34, and more preferably each has at least five second sliding-support elements 34.

The individual second sliding-support elements 34 are each formed by roller elements 37. The individual roller elements 37 of the first roller unit 35 are spaced apart one after the other along a first straight line on a housing 38 of the magnetic resonance apparatus 10 surrounding the patient-receiving area 14. The individual roller elements 37 of the second roller unit 36 are spaced apart one after the other along a second straight line on a housing 38 surrounding the patient-receiving area 14 (FIGS. 2 and 3). The rotation axes of the individual roller elements 37 of the first roller unit 35 are arranged one after another at a distance from one another on the first straight line, and the rotation axes of the individual roller elements 37 of the second roller unit 35 are arranged one after another at a distance from one another on the second straight line. The two straight lines are in this case aligned parallel to a longitudinal extent 39 of the patient-receiving area 14 and/or parallel to a direction of movement of an introductory movement of the patient bed 17 in the patient-receiving area 14 and/or parallel to the basic magnetic field 13. In addition, the two straight lines are perpendicular to a direction 40 of a gravitational force acting on the magnetic resonance apparatus 10.

During movement of the patient bed 17 inside the patient-receiving area 14, at least individual roller elements 37 of the first roller unit 35 are guided within the first C-shaped rail 27 and at least individual roller elements 34 of the second roller unit 36 within the second C-shaped rail 27. In this case, the patient bed 17 lies on the first and second roller units 35, 36 such that the roller elements 34 of the first roller unit 35 and the roller elements 34 of the second roller unit 36 engage (contact) the first sliding surface 32. In this case, the first sliding surface 32 of the C-shaped rails 27 is arranged on a side of the respective C-shaped rails 27 in the direction 40 of a gravitational force acting on the patient bed 17.

For secure positioning of the patient bed 17 inside the patient-receiving area 14, the sliding-support 25 also has at least one third sliding-support element 41 (FIGS. 2 and 4). In the present exemplary embodiment, the sliding-support 25 has two third sliding-support elements 41 with a first of the two third sliding-support elements 41 being encompassed by the first roller unit 35 and a second of the two third sliding-support elements 41 being encompassed by the second roller unit 36. The two third sliding-support elements 41 are also formed by roller elements 42 arranged inside the patient-receiving area 14.

While the second sliding-support elements 34, in particular the rotation axes of the second sliding-support elements 34, of the first roller unit 35 are arranged on the first straight line inside the patient-receiving area 14, the third sliding-support element 41 of the first roller unit 35 is arranged offset to the arrangement of the second sliding-support elements 34 inside the patient-receiving area 14. In this case, the third sliding-support element 41 is arranged offset downwardly relative to the second sliding-support elements 34 of the first roller unit 35 inside the patient-receiving area 14 in the direction 40 of the gravitational force acting on the patient bed 17 (FIG. 4).

While the second sliding-support elements 34, in particular the rotation axes of the second sliding-support elements 34, of the second roller unit 36 are arranged on the second straight line inside the patient-receiving area 14, the third sliding-support element 41 of the second roller unit 36 is arranged offset to the arrangement of the second sliding-support elements 34 inside the patient-receiving area 14. In this case, the third sliding-support element 41 is arranged offset downwardly relative to the second sliding-support elements 34 of the second roller unit 36 inside the patient-receiving area 14 in the direction 40 of the gravitational force acting on the patient bed 17 (FIG. 4).

The third sliding-support elements 41 of the first roller unit 35 and the second roller unit 36 are arranged in the direction of the longitudinal extension 39 of the patient-receiving area 14 in a region 43 of the center of the patient-receiving area 14. This ensures that, in the case of the only partial introduction of the patient bed 17 into the patient-receiving area 14, for example for a head examination on the patient 15, with which the head is to be positioned in the center of the patient-receiving area 14, the patient bed 17 is additionally secured and/or supported by means of the third sliding-support elements 41 (FIGS. 2 and 4).

For the additional support and/or securing of the patient bed 17 by means of the third sliding-support elements 41, however, in this case the patient bed 17 must be introduced into the patient-receiving area 14 at least as far as the position at which the third sliding-support elements 41 are arranged. In this position of the patient bed 17, when the patient bed 17 is introduced inside the patient-receiving area 14 at least as far as the position at which the third sliding-support elements 41 are arranged inside the patient-receiving area 14, the third sliding-support element 41 of the first roller unit 35 lies on the second sliding surface 33 of the first C-shaped rail 27 of the patient bed 17 and the third sliding-support element 41 of the second roller unit 36 lies on the second sliding surface 33 of the second C-shaped rail 27 of the patient bed 17. The second sliding surfaces 33 of the C-shaped rails 27 are in this case arranged on a side of the C-shaped rails 27 facing against the direction 40 of a gravitational force acting on the patient bed 17 (FIGS. 2 and 4).

When the patient bed 17 is introduced into the patient-receiving area 14 as far as the position of the third sliding-support elements 41, the third sliding-support elements 41 cause the patient bed 17 to be secured against unwanted displacement, in particular in the direction 40 of the gravitational force or against the direction 40 of the gravitational force. This facilitates snug positioning of the patient bed 17 for a magnetic resonance examination for example on the head of the patient 15. In addition, in this way, the third sliding-support elements 41 can also achieve stabilization of the position of the patient bed 17 in a direction perpendicular to the direction 40 of the gravitational force.

With a further introduction of the patient bed 17 into the patient-receiving area 14, the third sliding-support elements 41 can lose their stabilizing and/or supportive function with respect to the patient bed 17 since, in this case, the patient bed 17 is securely mounted on a larger number of second sliding-support elements 34 and, in addition, the weight of the patient 15 can cause the patient bed 17 to be slightly deformed so that there is no need for contact between the third sliding-support elements 41 and the second sliding surfaces 33.

A direction aligned against the gravitational force acting on the patient bed 17 can correspond to a y-direction of a coordinate system of the magnetic resonance apparatus 10.

In an alternative embodiment of the invention, the sliding-support 25 can have more than two third sliding-support elements 41. The first roller unit 35 could have, for example, two third sliding-support elements 41 and the second roller unit 36 could also have, for example, two third sliding-support elements 41.

In addition, the number of the second sliding-support elements 34 can vary from the number depicted herein, in alternative embodiments of the invention.

Although modifications and changes may be suggested by those skilled in the art, it is the intention of the inventors to embody within the patent warranted hereon all changes and modifications as reasonably and properly come within the scope of their contribution to the art.

We claim as our invention:

1. A magnetic resonance imaging apparatus comprising:
a magnetic resonance scanner comprising a patient-receiving receptacle;
a patient bed adapted to receive a patient thereon;
a sliding-support that moveably mounts said patient bed for movement and support into and out of said patient-receiving receptacle;
said sliding-support comprising a first sliding-support element attached to said patient bed, said first sliding-support element comprising two sliding surfaces;
said sliding-support further comprising at least two second sliding-support elements mounted inside said patient-receiving receptacle and in contact with said first sliding surface of said first sliding-support element; and
said sliding-support further comprising at least one third sliding-support element mounted inside said patient-receiving receptacle and in contact with said second sliding surface of said first sliding-support element when said patient bed is only partially inserted into said patient-receiving receptacle.

2. A medical imaging apparatus as claimed in claim 1 wherein said first sliding surface is situated opposite said second sliding surface on said first sliding-support element.

3. A medical imaging apparatus as claimed in claim 1 wherein said patient bed is movable in a movement direction into and out of said patient-receiving receptacle, and wherein said at least one third sliding-support element is situated at the center of said patient-receiving receptacle along said movement direction.

4. A medical imaging apparatus as claimed in claim 1 wherein said first sliding-support element comprises a C-shaped rail that forms said first and second sliding surfaces.

5. A medical imaging apparatus as claimed in claim 1 wherein said sliding-support comprises two first sliding-support elements situated on opposite edges of said patient bed and said edges proceeding in a direction of movement of said patient bed into and out of said patient-receiving receptacle.

6. A medical imaging apparatus as claimed in claim 5 wherein said sliding-support comprises a first roller unit and a second roller unit, said first roller unit comprising at least two of said second sliding-support elements and said second roller unit comprising at least two of said second sliding-support elements.

7. A medical imaging apparatus as claimed in claim 6 wherein said sliding-support comprises two third sliding-support elements, said first roller unit and said second roller unit each comprising one of said two third sliding-support elements.

8. A medical imaging apparatus as claimed in claim 7 wherein said third sliding-support element of said first roller unit is mounted offset of a straight line proceeding through the at least two second sliding-support elements of said first roller unit, and wherein said third sliding-support element of said second roller unit is situated offset of a straight line proceeding through said at least two second sliding-support elements of said second roller unit.
